(19) United States
(12) Patent Application Publication
(10) Pub. No.: US 2024/0283408 A1
(43) Pub. Date: Aug. 22, 2024

(54) AMPLIFICATION CIRCUIT, POWER AMPLIFICATION CIRCUIT, AND BIAS GENERATION CIRCUIT

(71) Applicant: Murata Manufacturing Co., Ltd., Kyoto (JP)

(72) Inventor: Makoto TABEI, Kyoto (JP)

(21) Appl. No.: 18/441,038

(22) Filed: Feb. 14, 2024

(30) Foreign Application Priority Data
Feb. 17, 2023 (JP) 2023-023365

(51) Int. Cl. H03F 1/30; H03F 1/02; H03F 3/21

(52) U.S. Cl. CPC H03F 1/301; H03F 1/0222; H03F 3/21; H03F 2200/441

(57) ABSTRACT

An amplification circuit includes an input terminal to which a signal to be amplified is input, a first FET having a gate to which a signal input to the input terminal is applied, second and third FETs that are connected between a power supply and a reference potential, an output terminal that is provided between a load and the third FET nearest to the power supply and configured to output an amplified signal, a voltage-dividing resistor circuit configured to generate a bias to be applied to gates of the second and third FETs, and a clamping circuit configured to clamp a bias to be applied to the gate of the third FET when a bias to be applied from the voltage-dividing resistor circuit to the gate of the second FET exceeds a predetermined reference voltage. The first to third FETS are vertically stacked and connected.

### CROSS REFERENCE TO RELATED APPLICATION

This application claims priority from Japanese Patent Application No. 2023-023365 filed on Feb. 17, 2023. The content of this application is incorporated herein by reference in its entirety.

### BACKGROUND ART

The present disclosure relates to an amplification circuit, a power amplification circuit, and a bias generation circuit.

An amplification circuit is known in which transistors, which are amplifying elements, are vertically stacked and connected (see, for example, Japanese Unexamined Patent Application Publication No. 8-097643). The amplification circuit disclosed in Japanese Unexamined Patent Application Publication No. 8-097643 includes a plurality of stages of transistors between a power supply and a reference potential. A signal to be amplified is input to the base of one of the transistors in the multiple stages which is nearest to a ground potential. A load is connected between the power supply and one of the transistors in the multiple stages which is nearest to the power supply.

In a communication device, a power-supply voltage is not constant and varies in some cases. For example, a power-supply voltage varies depending on the output power of a mobile communication device, that is, a power mode in some cases. If the amplification circuit disclosed in Japanese Unexamined Patent Application Publication No. 8-097643 is used in such a case, the following problems arise. That is, in the case where the gate bias of the transistor is set on the basis of a high power-supply voltage, a gate voltage may be too high and exceed the withstand voltage of the transistor when the power-supply voltage decreases. On the other hand, in the case where the gate bias of the transistor is set on the basis of a low power-supply voltage, a gate voltage may be too low and exceed the withstand voltage of the transistor when the power-supply voltage increases.

The present disclosure provides an amplification circuit, a power amplification circuit, and a bias generation circuit with which a gate bias not exceeding the withstand voltage of a transistor can be applied even when a power-supply voltage varies.

### BRIEF SUMMARY

An amplification circuit according to an aspect of the present disclosure includes an input terminal to which a signal to be amplified is input, a first field-effect transistor (FET) having a gate to which a signal input to the input terminal is applied, a second FET and a third FET that, along with the first FET, are connected between a power supply and a reference potential, an output terminal that is provided between a load and the third FET nearer to the power supply than the second FET and that is configured to output an amplified signal, a voltage-dividing resistor circuit configured to generate a bias to be applied to each of respective gates of the second FET and the third FET, and a clamping circuit configured to clamp a bias to be applied to the gate of the third FET when a bias to be applied from the voltage-dividing resistor circuit to the gate of the second FET exceeds a predetermined reference voltage. The first FET, the second FET, and the third FET are vertically stacked and connected.

An amplification circuit according to another aspect of the present disclosure includes a plurality of FETs in which a drain and a source adjacent to each other are connected. Respective voltages generated by voltage dividing performed by a plurality of series-connected resistors are set as biases. The biases are applied to corresponding gates of the plurality of FETs. When one of the biases exceeds a predetermined reference voltage, another one of the biases is clamped.

A power amplification circuit according to the present disclosure includes any one of the above-described amplification circuits as a driver-stage amplification circuit and a power-stage amplification circuit to which an output of the driver-stage amplification circuit is input.

A bias generation circuit according to the present disclosure includes a voltage-dividing resistor circuit that includes series-connected resistors in at least three stages and that is configured to generate a bias from each of the at least three stages by voltage dividing and a clamping circuit configured to, when the bias generated in a certain one of the at least three stages exceeds a predetermined reference voltage, clamp the bias in another one of the at least three stages nearer to a power supply than the certain stage. The biases are applied to corresponding gates of a plurality of FETs in which a drain and a source adjacent to each other are connected.

According to the present disclosure, a gate bias not exceeding the withstand voltage of a transistor can be applied even when a power-supply voltage varies.

### BRIEF DESCRIPTION OF THE DRAWINGS

FIG. 1 is a diagram describing the case where a power amplifier is created using a bipolar transistor;

FIG. 2 is a diagram describing the case where a power amplifier is created using a field-effect transistor;

FIG. 3 is a diagram illustrating an example of a vertical-stacking connection of a plurality of FETs;

FIG. 4 is a diagram illustrating an exemplary configuration of an amplifier when a power-supply voltage is constant;

FIG. 5 is a diagram illustrating an exemplary configuration of an amplifier when a power-supply voltage varies;

FIG. 6 is a diagram illustrating the state of a drain-to-source voltage in each stage of FETs that are vertically stacked and connected when a power-supply voltage is relatively high;

FIG. 7 is a diagram illustrating the state of a drain-to-source voltage in each stage of FETs that are vertically stacked and connected when a power-supply voltage is relatively low;

FIG. 8 is a circuit diagram of an amplification circuit according to a first comparative example;

FIG. 9 is a diagram illustrating an exemplary operation of the amplification circuit illustrated in FIG. 8;

FIG. 10 is a diagram illustrating an exemplary operation of the amplification circuit illustrated in FIG. 8;

FIG. 11 is a circuit diagram of an amplification circuit according to a second comparative example;

FIG. 12 is a diagram illustrating an exemplary operation of the amplification circuit illustrated in FIG. 11;

FIG. 13 is a diagram illustrating an exemplary operation of the amplification circuit illustrated in FIG. 11;

FIG. 14 is a circuit diagram of an amplification circuit according to a first embodiment;

FIG. 15 is a diagram illustrating an exemplary operation of the amplification circuit illustrated in FIG. 14;

FIG. 16 is a diagram illustrating an exemplary operation of the amplification circuit illustrated in FIG. 14;

FIG. 17 is a diagram illustrating an exemplary operation of the amplification circuit illustrated in FIG. 14;

FIG. 18 is a circuit diagram of an amplification circuit according to a second embodiment;

FIG. 19 is a circuit diagram of an amplification circuit according to a third embodiment;

FIG. 20 is a circuit diagram of an amplification circuit according to a fourth embodiment; and

FIG. 21 is a circuit diagram illustrating an example of a hybrid amplification circuit in which a driver stage is made of Si and a power stage is made of GaAs.

### DETAILED DESCRIPTION

Embodiments of the present disclosure will be described in detail below with reference to drawings. In the following description of each embodiment, the same reference numerals are given to the same or equivalent components as those in other embodiments, and the description thereof will be simplified or omitted. The present disclosure is not limited to the embodiments. The constituent elements of each of the embodiments include those that can be easily replaced by a person skilled in the art or those that are substantially the same. Note that the configurations to be described below can be combined as appropriate. In addition, the configurations can be omitted, replaced, or changed without necessarily departing from the gist of the disclosure.

First, comparative examples will be described below for ease of understanding of the embodiments.

### Comparative Example

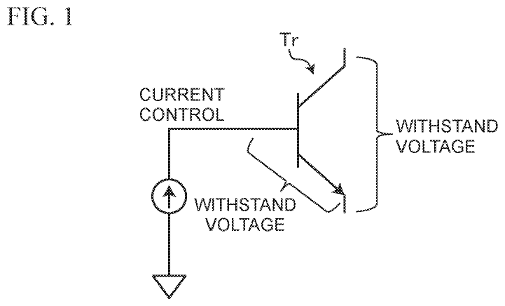

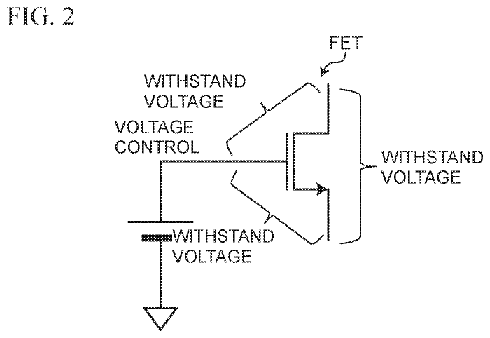

FIG. 1 is a diagram describing the case where a power amplifier is created using a bipolar transistor. FIG. 2 is a diagram describing the case where a power amplifier is created using a field-effect transistor.

FIG. 1 illustrates the case where a power amplifier (hereinafter referred to as a “PA” in some cases) is created using a bipolar transistor Tr made of GaAs. The bipolar transistor Tr is a current-control type element that is controlled in accordance with a current applied to the base thereof.

FIG. 2 illustrates a field-effect transistor (hereinafter referred to as an FET). An FET is a voltage-control type element that is controlled in accordance with a voltage applied to the gate thereof. An FET used as a silicon on insulator (SOI) complementary metal-oxide-semiconductor (CMOS) PA is subjected to a miniaturization process for improvement of performance of the FET (e.g., a cutoff frequency ft and a mutual conductance gm). Accordingly, the withstand voltage of an FET used as an SOI CMOS PA is lower than that of the bipolar transistor Tr formed of GaAs.

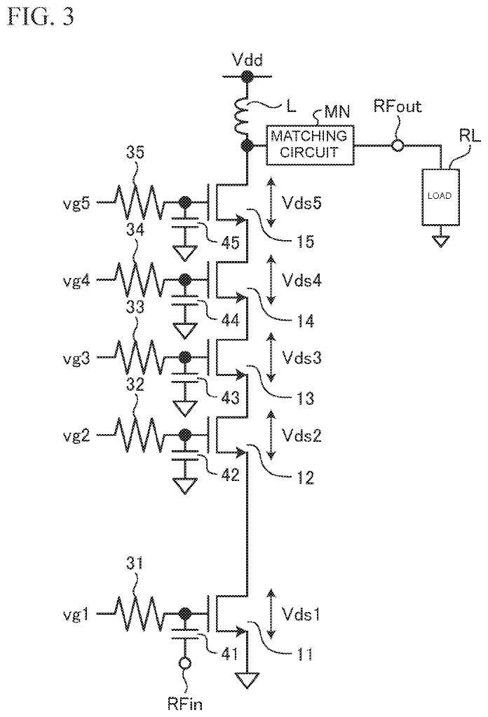

A configuration is considered in which a plurality of FETs are vertically stacked and connected (hereinafter referred to as vertical-stacking connection) between a power supply Vdd and a reference potential. FIG. 3 is a diagram illustrating an example of vertical-stacking connection of a plurality of FETs. FIG. 3 illustrates an example of five-stage vertical-stacking connection of five FETs. Referring to FIG. 3, FETs 11, 12, 13, 14 and 15 are vertically stacked and connected between the reference potential and the power supply Vdd. The reference potential is, for example, a ground potential. In the vertical-stacking connection illustrated in FIG. 3, the drain and source of the consecutively connected FETs which are adjacent to each other are connected. In the present specification, the inconsecutive connection of the FETs provided between the reference potential and the power supply Vdd is called the vertical-stacking connection of the FETs in some cases. Focusing on, for example, the FETs 12 and 14, the FETs 12 and 14 are not connected to each other because the FET 13 is present therebetween. A vertical-stacking connection includes such an indirect connection. The same can be said in the following description.

Resistors 31, 32, 33, 34, and 35 are connected to the gates of the FETs 11, 12, 13, 14 and 15, respectively. Capacitors 41, 42, 43, 44, and 45 are provided between the gates of the FETs 11, 12, 13, 14 and 15 and the reference potential, respectively. The gate of the FET 11 is connected to an input terminal RFin via the capacitor 41. A choke coil L is connected between the FET 15 and the power supply Vdd. An output terminal RFout is connected between the FET 15 and the choke coil L via a matching circuit MN. A load RL is connected to the output terminal RFout. A portion including the load RL, the choke coil L, and the matching circuit MN is viewed as a load impedance as viewed from the drain of the FET 15.

The source-to-drain voltage of the FET 11 is defined as a voltage Vds1, the source-to-drain voltage of the FET 12 is defined as a voltage Vds2, the source-to-drain voltage of the FET 13 is defined as a voltage Vds3, the source-to-drain voltage of the FET 14 is defined as a voltage Vds4, and the source-to-drain voltage of the FET 15 is defined as a voltage Vds5. In order to prevent the FETs 11, 12, 13, 14 and 15 from being broken, the values of the voltages Vds1, Vds2, Vds3, Vds4, and Vds5 need to be lower than or equal to a withstand voltage at the time of the maximum value of the power supply Vdd. Accordingly, there is the need to control the voltage values of biases vg1, vg2, vg3, vg4, and vg5 applied to respective gates to prevent the respective source-to-drain voltages from exceeding the withstand voltage.

The case where the voltage value of the power supply Vdd is fixed and the case where the voltage value of the power supply Vdd varies are considered. FIG. 4 is a diagram illustrating an exemplary configuration of an amplifier when a power-supply voltage is constant. As illustrated in FIG. 4, a power-supply voltage Vdd generated by a low dropout (LDO) regulator is input to a PA. The PA amplifies an input signal S1 and outputs the amplified signal as an output signal S2. A power-supply voltage V10 for the PA is constant irrespective of output power V11.

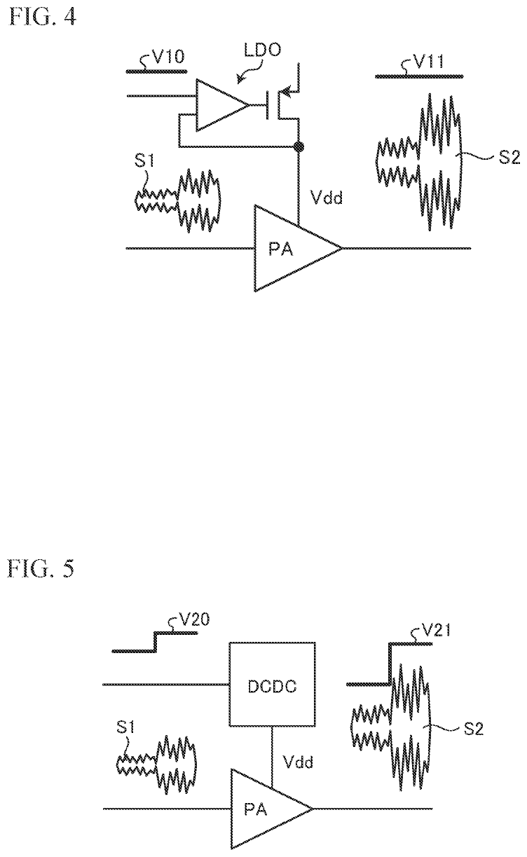

In the case of, for example, a power supply for an amplifier used in a communication device in a cellular phone network, a power-supply voltage varies depending on a power mode for reduction of power consumption. FIG. 5 is a diagram illustrating an exemplary configuration of an amplifier when a power-supply voltage varies. When a power mode changes, the changed power-supply voltage Vdd is input to the PA. A power-supply voltage V20 needs to be changed in accordance with output power V21. For example, the power-supply voltage Vcc, the voltage values of which has been changed by a DC-DC converter, is input to the PA.

When a power-supply voltage is changed depending on a power mode, the power-supply voltage needs to be controlled so as not to exceed the withstand voltage of an FET. By vertically stacking and connecting FETs as illustrated in FIG. 3, a voltage applied to each stage can be less than or equal to a withstand voltage. If the gate bias of a transistor is set on the basis of a high power-supply voltage, a gate voltage may be too high and exceed the withstand voltage of the transistor when the power-supply voltage decreases. On the other hand, if the gate bias of the transistor is set on the basis of a low power-supply voltage, a gate voltage may be too low and exceed the withstand voltage of the transistor when the power-supply voltage increases. A gate bias needs to be controlled to follow the voltage of the power supply Vdd so as not to exceed the withstand voltage of a transistor.

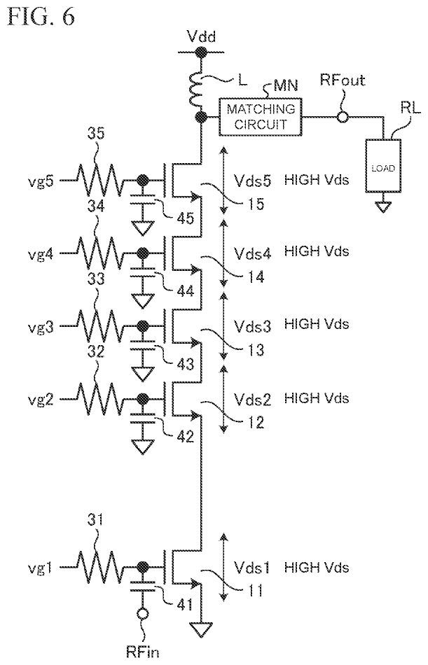

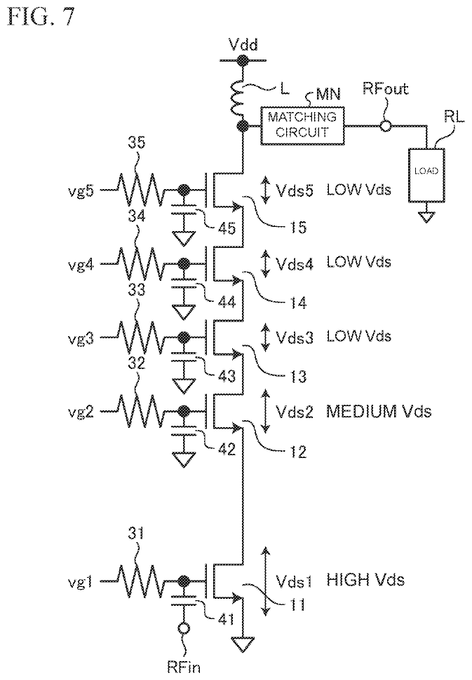

FIG. 6 is a diagram illustrating the state of a drain-to-source voltage Vds in each stage of FETs that are vertically stacked and connected when the power supply Vdd is relatively high. In the case illustrated in FIG. 6, for example, a power-supply voltage has the maximum value. In the case illustrated in FIG. 6, the voltage Vds is evenly distributed to respective stages of FETs. That is, “High Vds” indicating that the voltage Vds is high is illustrated in each stage of FETs.

FIG. 7 is a diagram illustrating the state of the drain-to-source voltage Vds in each stage of FETs that are vertically stacked and connected when the power supply Vdd is relatively low. In the case illustrated in FIG. 7, for example, a power-supply voltage has a value lower than the maximum value. In the case illustrated in FIG. 7, “High Vds” indicating that the voltage Vds is high is illustrated for the voltage Vds1 of the FET 11 nearest to the reference potential. “Medium Vds” indicating that the voltage Vds is at a medium level is illustrated for the voltage Vds2 of the FET 12 that is second nearest to the reference potential. “Low Vds” indicating that the voltage Vds is low is illustrated for the Vds3 of the FET 13, the voltage Vds4 of the FET 14, and the voltage Vds5 of the FET 15. In the case where a gate bias is controlled to follow the voltage of the power supply Vdd, there is the need to control the gate bias as illustrated in FIGS. 6 and 7.

### First Comparative Example

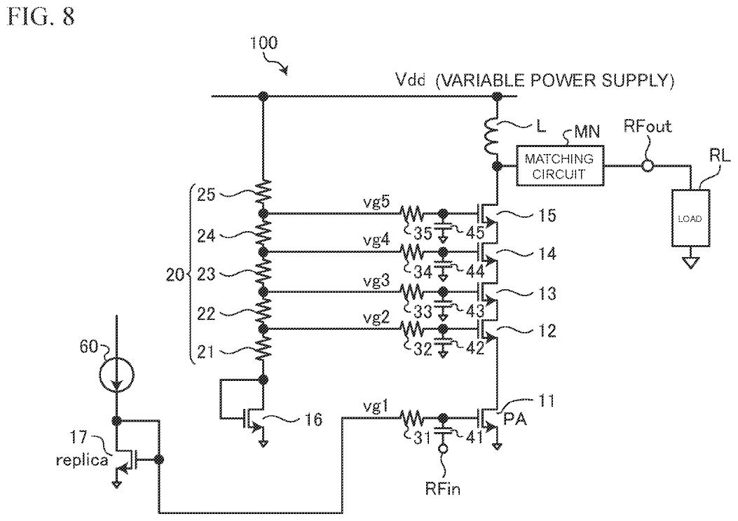

FIG. 8 is a circuit diagram of an amplification circuit 100 according to the first comparative example. Referring to FIG. 8, the amplification circuit 100 according to the present example includes the FETs 11, 12, 13, 14 and 15, resistors 21, 22, 23, 24, and 25, the resistors 31, 32, 33, 34, and 35, the capacitors 41, 42, 43, 44, and 45, and an FET 16.

The FETs 11, 12, 13, 14 and 15 are provided between a reference potential and the power supply Vdd. The FETs 11, 12, 13, 14 and 15 are vertically stacked and connected. That is, the drain of the FET 11 is connected to the reference potential, and the source of the FET 11 is connected to the drain of the FET 12. The source of the FET 12 is connected to the drain of the FET 13. The source of the FET 13 is connected to the drain of the FET 14. The source of the FET 14 is connected to the drain of the FET 15. The source of the FET 15 is connected to the power supply Vdd via the choke coil L. The output terminal RFout is connected between the source of the FET 15 and the choke coil L via the matching circuit MN. In the present specification, the FETs 11, 12, 13, 14, and 15 are referred to as a first FET, a second FET, a third FET, a fourth FET, and a fifth FET, respectively in some cases.

The power supply Vdd is a variable power supply, and the voltage value of the power supply Vdd is not a fixed value and varies. The choke coil L is connected between the power supply Vdd and the power-supply-Vdd side of the FET 15 that is nearest to power supply Vdd of the FETs 11 to 15 that are vertically stacked and connected. The output terminal RFout is connected between the choke coil L and the FET 15 via the matching circuit MN. The load RL is connected to the output terminal RFout.

The resistor 31 and the capacitor 41 are provided in correspondence with the FET 11. One end of the resistor 31 and one end of the capacitor 41 are connected to the gate of the FET 11. The input terminal RFin is connected to the other end of the capacitor 41. A signal to be amplified is input to the input terminal RFin.

The resistor 32 and the capacitor 42 are provided in correspondence with the FET 12. One end of the resistor 32 and one end of the capacitor 42 are connected to the gate of the FET 12. The other end of the capacitor 42 is connected to the reference potential.

The resistor 33 and the capacitor 43 are provided in correspondence with the FET 13. One end of the resistor 33 and one end of the capacitor 43 are connected to the gate of the FET 13. The other end of the capacitor 43 is connected to the reference potential.

The resistor 34 and the capacitor 44 are provided in correspondence with the FET 14. One end of the resistor 34 and one end of the capacitor 44 are connected to the gate of the FET 14. The other end of the capacitor 44 is connected to the reference potential.

The resistor 35 and the capacitor 45 are provided in correspondence with the FET 15. One end of the resistor 35 and one end of the capacitor 45 are connected to the gate of the FET 15. The other end of the capacitor 45 is connected to the reference potential.

The drain and gate of the FET 16 are connected to establish a so-called diode connection. The FET 16 is provided between the resistor 21 and the reference potential.

The resistors 21, 22, 23, 24, and 25 are ladder resistors connected in series between the power supply Vdd and the reference potential. The resistors 21, 22, 23, 24, and 25 form a voltage-dividing resistor circuit 20. By forming the resistors 21, 22, 23, 24, and 25 with the same ladder resistors, the occurrence of, for example, a gate bias reversal in each stage due to the variation in pairing of resistors can be prevented. The “same ladder resistors” mean ladder resistors manufactured with the same material by the same process.

One end of the resistor 21 is connected to the drain and gate of the FET 16. One end of the resistor 21 is connected to the reference potential via the diode formed by the FET 16. The FET 16 is connected to the reference-potential side of the voltage-dividing resistor circuit 20. Accordingly, the FET 16 is provided between the voltage-dividing resistor circuit 20 and the reference potential.

In the voltage-dividing resistor circuit 20, the resistors 21 and 22 are connected in series. A node between the resistors 21 and 22 is connected to the other end of the resistor 32. The voltage of the node between the resistors 21 and 22 is applied to the gate of the FET 12 as the bias vg2. The resistors 22 and 23 are connected in series. A node between the resistors 22 and 23 is connected to the other end of the resistor 33. The voltage of the node between the resistors 22 and 23 is applied to the gate of the FET 13 as the bias vg3. The resistors 23 and 24 are connected in series. A node between the resistors 23 and 24 is connected to the other end of the resistor 34. The voltage of the node between the resistors 23 and 24 is applied to the gate of the FET 14 as the bias vg4. The resistors 24 and 25 are connected in series. A node between the resistors 24 and 25 is connected to the other end of the resistor 35. The voltage of the node between the resistors 24 and 25 is applied to the gate of the FET 15 as the bias vg5.

Referring to FIG. 8, the amplification circuit 100 according to the present example includes an FET 17 and a constant current source 60. The constant current source 60 outputs a constant current. The FET 17 is connected to the output side of the constant current source 60. The drain and gate of the FET 17 are connected to establish a so-called diode connection. The other end of the resistor 31 is connected to the FET 17. The FET 17 is a replica transistor forming a current mirror circuit along with the FET 11. The current mirror circuit formed by the FETs 11 and 17 flows a current proportional to a constant current output from the constant current source 60 between the drain and source of the FET 11.

### Operation According to First Comparative Example

In the amplification circuit 100 illustrated in FIG. 8, a bias generated by resistor voltage dividing performed by the voltage-dividing resistor circuit 20 is applied to the respective gates of the FETs 12 to 15. The amplification circuit 100 amplifies a radio-frequency signal input to the input terminal RFin. The amplification circuit 100 outputs the amplified signal from the output terminal RFout.

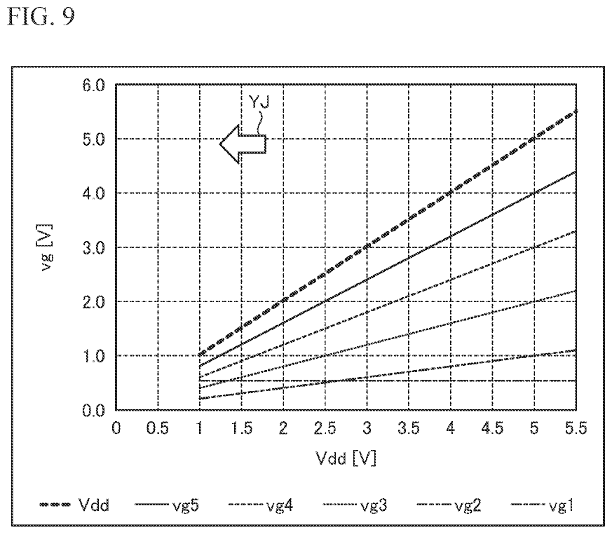

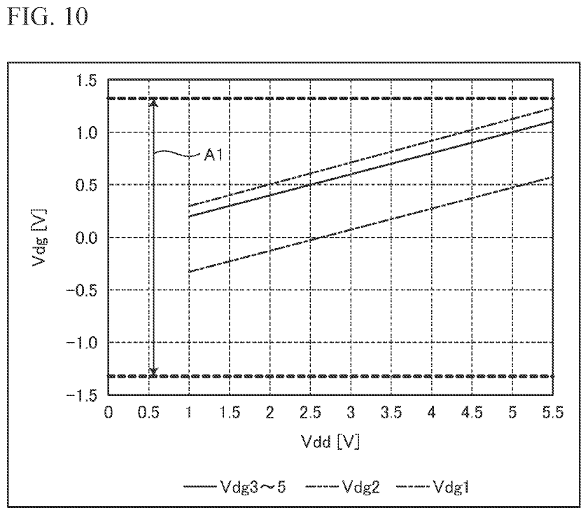

FIGS. 9 and 10 are diagrams illustrating an exemplary operation of the amplification circuit 100 illustrated in FIG. 8. FIG. 9 is a diagram illustrating a simulation result of a bias applied to the gate of each FET in the amplification circuit 100. Referring to FIG. 9, the horizontal axis represents a voltage value [V] of the power supply Vdd and the vertical axis represents a voltage value [V] of a voltage vg of a bias applied to the gate of an FET (i.e., a gate bias). FIG. 9 illustrates the change in the voltage value of each bias with respect to the change in the voltage value of the power supply Vdd. A gate bias is hereinafter abbreviated as a “bias” in some cases.

Referring to FIG. 9, the respective voltage values of the biases vg2 to vg5 change in response to the change in the voltage value of the power supply Vdd. The voltage value of the bias vg1 is constant. When the voltage value of the power supply Vdd decreases, the voltage values of, in particular, the biases vg2 and vg3 on the low-potential side (the side near the reference potential) falls too low as represented by an arrow YJ in FIG. 9.

FIG. 10 is a diagram illustrating a simulation result of a potential difference between a drain and a gate. Referring to FIG. 10, the horizontal axis represents a voltage value [V] of the power supply Vdd and the vertical axis represents a voltage value Vdg [V] between a drain and a gate. A two-headed arrow in FIG. 10 represents an unbroken region A1. An FET is not broken when operating in the unbroken region. As illustrated in FIG. 10, the voltage values of all the biases vg1 to vg5 are in the unbroken region A1.

### Second Comparative Example

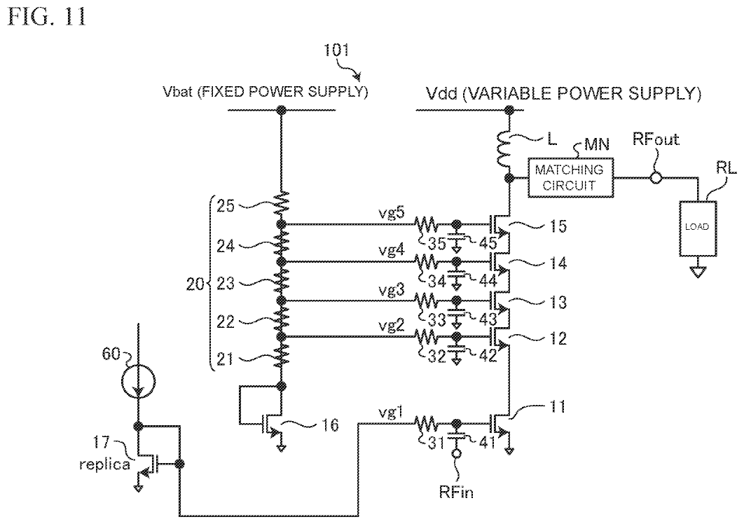

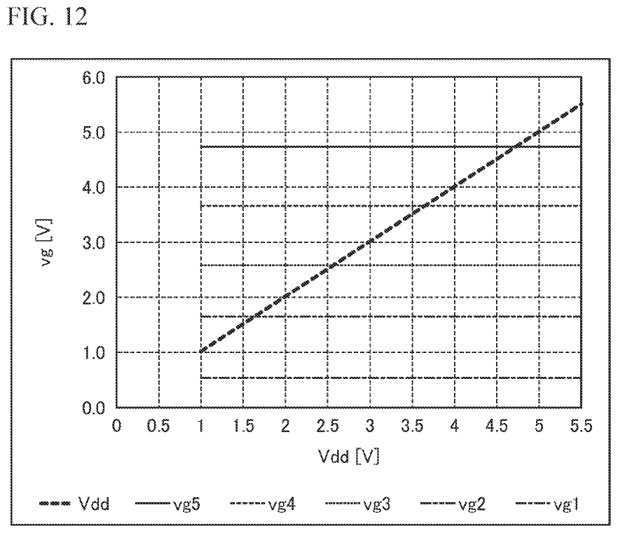

FIG. 11 is a circuit diagram of an amplification circuit 101 according to the second comparative example. The amplification circuit 101 according to the present example illustrated in FIG. 11 differs from the amplification circuit 100 described with reference to FIG. 8 in that a bias is generated using a fixed power supply in addition to the power supply Vdd that is a variable power supply. For example, a power supply Vbat that is the output of a battery of a mobile communication device is used. The power supply Vdd for the FETs 11, 12, 13, 14 and 15 that are vertically stacked and connected is a variable power supply like in FIG. 8. The other configuration of the amplification circuit 101 illustrated in FIG. 11 is the same as that of the amplification circuit 100 described with reference to FIG. 8.

If a gate bias is set on the basis of a high voltage value of the power supply Vdd in the amplification circuit 101 according to the second comparative example, a gate potential may be too high and exceed the unbroken region when the voltage of the power supply Vdd decreases. If a gate bias is set on the basis of a low voltage value of the power supply Vdd, a gate potential may be too low and exceed the unbroken region when the voltage of the power supply Vdd increases.

### Operation According to Second Comparative Example

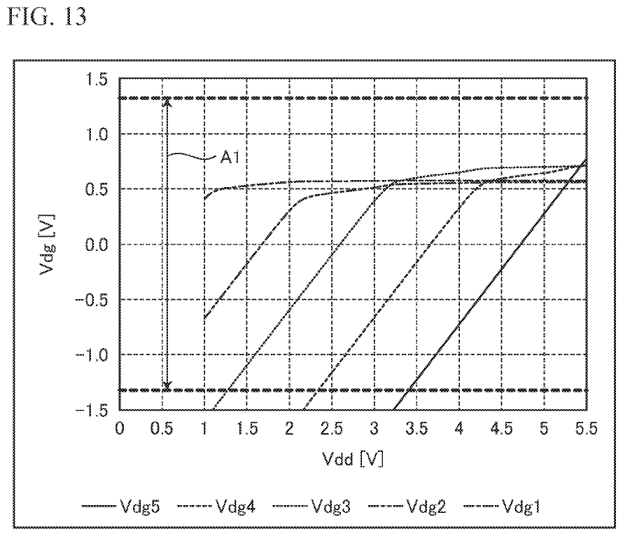

FIGS. 12 and 13 are diagrams illustrating an exemplary operation of the amplification circuit 101 illustrated in FIG. 11. FIG. 12 is a diagram illustrating a simulation result of a bias applied to the gate of each FET in the amplification circuit 101. Referring to FIG. 12, the horizontal axis represents a voltage value [V] of the power supply Vdd and the vertical axis represents a voltage value [V] of the voltage vg of a bias applied to the gate of an FET (i.e., a gate bias). FIG. 12 illustrates the change in the voltage value of each bias with respect to the change in the voltage value of the power supply Vdd. As illustrated in FIG. 12, the voltage values of the biases vg1 to vg5 are constant even when the voltage value of the power supply Vdd varies.

FIG. 13 is a diagram illustrating a simulation result of a potential difference between a drain and a gate. Referring to FIG. 13, the horizontal axis represents a voltage value [V] of the power supply Vdd and the vertical axis represents the voltage value Vdg [V] between a drain and a gate. If a gate bias is set on the basis of a high voltage value of the power supply Vdd, a gate potential may be too high and exceed the unbroken region A1 when the voltage of the power supply Vdd decreases as illustrated in FIG. 13. In the present example, a voltage value Vdg1 corresponding to the bias vg1 and a voltage value Vdg2 corresponding to the bias vg2 are in the unbroken region A1. In contrast, a voltage value Vdg3 corresponding to the bias vg3, a voltage value Vdg4 corresponding to the bias vg4, and a voltage value Vdg5 corresponding to the bias vg5 decrease to the outside of the unbroken region A1. At that time, the difference between the voltage value Vdg5 and each of the voltage values Vdg3, Vdg4, and Vdg5 may become large, the voltage values Vdg3, Vdg4, and Vdg5 may exceed a withstand voltage, and the FETs 13, 14, and 15 may be broken.

### Point of Amplification Circuit According to Present Disclosure

As a method of solving the above problems, a method of controlling a gate bias to follow the change in the power supply Vdd is considered. That is, a bias is set such that the drain-to-source voltage Vds of an FET is equally distributed when the voltage of the power supply Vdd is high. When the voltage of the power supply Vdd is low, a bias setting is performed such that the voltage values Vds3, Vdg4, and Vdg5 corresponding to the FETs 3, 4, and 5 in an upper stage of a vertical-stacking connection become relatively small while the large voltage values Vdg1 and Vdg2 corresponding to the FETs 1 and 2 in a lower stage of the vertical-stacking connection are ensured.

In an amplification circuit according to the present disclosure, the power supply Vdd that is a variable power supply is subjected to voltage dividing in the voltage-dividing resistor circuit 20 formed of ladder resistors. In the voltage-dividing resistor circuit 20, a low voltage dividing ratio is set on the low-potential side on which the biases vg2 and vg3 are present. For example, in the case where the bias vg2 is subjected to voltage dividing of (⅕)×Vdd, the bias vg2=1 [V] is satisfied when the power supply Vdd=5 [V]. In the case where the voltage dividing ratio is increased to (½) Vdd, vg2=2.5 [V] is satisfied when the power supply Vdd=5 [V]. Thus, by increasing a voltage dividing ratio, voltages such as the biases vg2 and vg3 are prevented from falling too low when the voltage value of the power supply Vdd varies and decreases. However, if a voltage dividing ratio is simply increased, a bias is too high when the voltage value of the power supply Vdd is high. A clamping circuit is therefore provided to clamp the voltage of the bias vg3 to a desired potential when the voltage value of the power supply Vdd is high. The biases vg4 and vg5 required to have higher voltages are set to have higher voltages. Such a configuration is employed.

With an amplification circuit according to the present disclosure, the following effects can be obtained. (1) An optimum bias can be set in the wide voltage range of the power supply Vdd, countermeasures against the destruction of an FET can be taken, and the characteristics of an FET can be maintained. The degree of freedom in controlling the voltage value of the power supply Vdd is high, and the effect of changing the voltage value of the power supply Vdd can be easily obtained. (2) The configuration of an amplification circuit can be simplified, and the increase in the footprint of the amplification circuit can be minimized. (3) By forming the biases vg2 to vg5 with the same ladder resistors, the occurrence of, for example, a gate bias reversal in each stage due to the variation in pairing of resistors can be prevented. (4) The drain-to-source voltage Vds of an FET in a lower stage of a vertical-stacking connection for radio-frequency characteristics can be determined with high accuracy.

To ensure the characteristics of a PA, it is desired that the values of the drain-to-source voltages Vds1 and Vds2 be as high as possible even when the voltage of the power supply Vdd is low. Accordingly, when the voltage value of the power supply Vdd is low, biases on the upper stage side of the vertical-stacking connection in a PA inevitably become low. In a PA having a vertical-stacking connection, the drain-to-source voltage Vds on the upper stage side becomes low and a linear region operation is performed at the time of a low-voltage operation. Accordingly, the effect of an on-resistance becomes visible and an output is less likely to be produced.

In the present disclosure, the voltage dividing ratios of respective stages in a voltage-dividing resistor circuit are not set to the same value but to different values. Specifically, the resistor voltage dividing ratio for the biases vg2 and vg3 on the lower stage side of the vertical-stacking connection are increased such that a potential is less likely to decrease even when the voltage of the power supply Vdd is low, and a potential is clamped so as not to be too high when the voltage of the power supply Vdd is high. A configuration is employed in which the biases vg4 and vg5 requiring a high potential increase to follow the power supply Vdd. That is, a clamping circuit 50 monitors the voltage of the bias vg2, and the bias vg3 is clamped. The single clamping circuit 50 can therefore finely control the drain-to-source voltage Vds1 of the FET 11 in the undermost stage which is important for characteristics and the drain-to-source voltage Vds2 of the FET 12 in the stage one above the undermost stage. The biases vg4 and vg5 can be controlled such that the voltage values of them increase to follow the power supply Vdd even after the clamping circuit 50 has operated and satisfy the conditions of a withstand voltage when the voltage value of the power supply Vdd becomes maximum.

### First Embodiment

Next, embodiments will be described.

### Configuration

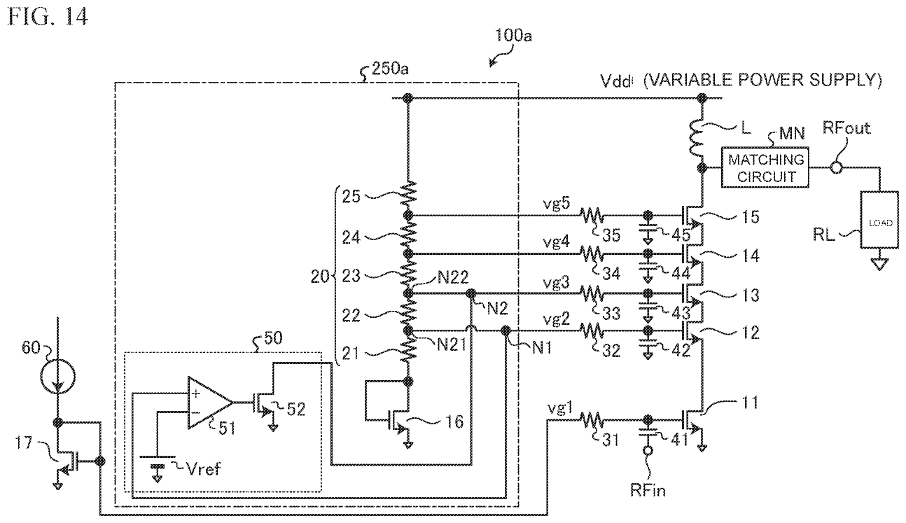

FIG. 14 is a circuit diagram of an amplification circuit 100a according to the first embodiment. The amplification circuit 100a illustrated in FIG. 14 has a configuration in which the clamping circuit 50 is added to the components in the amplification circuit 100 described with reference to FIG. 8. The clamping circuit 50 and the voltage-dividing resistor circuit 20 are included in a bias generation circuit 250a to be described below.

### Clamping Circuit

As illustrated in FIG. 14, the clamping circuit 50 according to the present embodiment includes a comparison circuit 51, a transistor 52, and a reference voltage Vref. The comparison circuit 51 can be formed by, for example, an operational amplifier. The comparison circuit 51 has a positive input terminal (+) and a negative input terminal (−). The predetermined reference voltage Vref is input to the negative input terminal of the comparison circuit 51. The voltage value of a node N1 is input to the positive input terminal of the comparison circuit 51. The node N1 is a point having the same potential as a node N21 between the resistors 21 and 22 in the present embodiment. The potential of the node N1 is the bias vg2.

The transistor 52 is an N-type MOS transistor in the present embodiment. The output terminal of the comparison circuit 51 is connected to the gate of the transistor 52. The source of the transistor 52 is connected to a reference potential. The drain of the transistor 52 is connected to a node N2. The node N2 is a point having the same potential as a node N22 between the resistors 22 and 23 in the present embodiment. The potential of the node N2 is the bias vg3.

The transistor 52 is a switching element that is turned on on the basis of the output of the comparison circuit 51. The comparison circuit 51 compares the voltage value of the bias vg2 applied from the voltage-dividing resistor circuit 20 to the gate of the FET 12 with the reference voltage Vref. The comparison circuit 51 applies a voltage for turning on the transistor 52 to the gate of the transistor 52 when the voltage value of the bias vg2 exceeds the reference voltage Vref.

In the clamping circuit 50, the output of the comparison circuit 51 is at a low level when the potential of the node N1 input to the positive input terminal of the comparison circuit 51, that is, the voltage value of the bias vg2, does not exceed the reference voltage Vref. At that time, the transistor 52 is in an OFF state.

When the potential of the node N1, that is, the voltage value of the bias vg2, exceeds the reference voltage Vref, the output of the comparison circuit 51 is at a high level. The transistor 52 is therefore turned on. When the transistor 52 is turned on, a current flows through the transistor 52 and the potential of the node N2 decreases. That is, by drawing a current from the node N2 on the path from the voltage-dividing resistor circuit 20 to the gate of the FET 13, the potential of the node N2 decreases. When the potential of the node N2 decreases, the potential of the N1 also decreases, a current flowing through the transistor 52 decreases, and feedback is applied such that the potential of the node N1 and the reference voltage Vref are equal. Accordingly, the voltage value of the bias vg3 is clamped such that the bias vg2 does not exceed the reference voltage Vref.

As described above, the clamping circuit 50 receives the input of the voltage of the node N1 having the same potential as the node N21 between the resistors 21 and 22. The clamping circuit 50 clamps the voltage of the node N2 having the same potential as the node N22 between the resistors 22 and 23.

That is, the amplification circuit 100a includes the input terminal RFin to which a signal to be amplified is input, the first FET 11 having a gate to which a signal input to the input terminal RFin is applied, the second FET 12 and the third FET 13 that are vertically stacked and connected between the power supply Vdd and the reference potential along with the first FET 11, the output terminal RFout that is provided between the power supply Vdd and the third FET 13, which is located nearer to the power supply Vdd than the second FET 12, and outputs an amplified signal, and the voltage-dividing resistor circuit 20 for generating the bias vg2 applied to the gate of the second FET 12 and the bias vg3 applied to the gate of the third FET 13. The amplification circuit 100a also includes the clamping circuit 50 for clamping the bias vg3 applied to the gate of the third FET 13 when the bias vg2 applied from the voltage-dividing resistor circuit 20 to the gate of the second FET 12 exceeds a predetermined reference voltage. In the amplification circuit 100a, the second FET 12, the third FET 13, the fourth FET 14, and the fifth FET 15 are vertically stacked and connected between the power supply Vdd and the reference potential along with the first FET 11.

By disposing the clamping circuit 50, the resistor voltage dividing ratios for the biases vg2 and vg3 increase (voltage dividing ratios increase) such that the potentials of the biases vg2 and vg3 are less likely to decrease when the voltage value of the variable power supply Vdd is low and the potentials of the biases vg2 and vg3 are clamped so as not to rise too high when the voltage value of the variable power supply Vdd is high. That is, the clamping circuit 50 controls the potentials of the biases vg2 and vg3, which are controlled to be less likely to decrease at the low voltage value of the power supply Vdd in such a manner that resistor voltage dividing ratios for the biases vg2 and vg3 are increased, such that they do not rise too high at the high voltage of the power supply Vdd.

### Voltage Value of Bias in Each Stage

The clamping circuit 50 is not disposed for biases requiring a high potential, such as the biases vg4 and vg5. The biases vg4 and vg5 are therefore configured to increase in voltage value to follow the power supply Vdd.

The value of the reference voltage Vref is represented by Vclamp, the voltage value of the power supply Vdd is represented by vdd, and a voltage corresponding to the FET 16 having a diode connection is represented by Vt. The voltage values of the biases vg2, vg3, vg4, and vg5 can be represented by the following equations (1) to (8).

When vg2≤Vclamp, the following equations are satisfied.

$$v g 2 = V t + ( V dd - V t ) / ( R 5 + R 4 + R 3 + R 2 + R 1 ) \times R 1 \qquad ( 1 )$$

$$v g 3 = V t + ( V dd - V t ) / ( R 5 + R 4 + R 3 + R 2 + R 1 ) \times ( R 1 + R 2 ) \qquad ( 2 )$$

$$v g 4 = V t + ( V dd - V t ) / ( R 5 + R 4 + R 3 + R 2 + R 1 ) \times ( R 1 + R 2 + R 3 ) \qquad ( 3 )$$

$$v g 5 = V t + ( V dd - V t ) / ( R 5 + R 4 + R 3 + R 2 + R 1 ) \times ( R 1 + R 2 + R 3 + R 4 ) \qquad ( 4 )$$

When vg2>Vclamp, the following equations are satisfied.

$$v g 2 = V clamp \qquad ( 5 )$$

$$v g 3 = V clamp + ( V clamp - V t ) / R 1 \times R 2 \qquad ( 6 )$$

$$v g 4 = v g 3 + ( V dd - v g 3 ) / ( R 5 + R 4 + R 3 ) \times R 3 \qquad ( 7 )$$

$$v g 5 = v g 3 + ( V dd - v g 3 ) / ( R 5 + R 4 + R 3 ) \times ( R 3 + R 4 ) \qquad ( 8 )$$

The voltage-dividing resistor circuit 20 includes the resistor 21 that is a first resistor, the resistor 22 that is a second resistor, and the resistor 23 that is a third resistor. The resistor 21 is disposed nearest to the reference potential. The resistor 22 is disposed nearer to the power supply Vdd than the resistor 21. The resistor 23 is disposed nearer to the power supply Vdd than the resistor 22. It is desired that the resistance values of the resistors 21 and 22 be larger than that of the resistor 23. It is desired that the resistance value of the resistor 21 be larger than that of the resistor 22. By setting the respective resistance values of the resistors as above, a bias not exceeding the withstand voltage of an FET can be applied to the gate of the FET with more certainty even when the voltage value of the power supply Vdd varies. In the case of 5-stage vertical-stacking connection, it is desired that the resistance value of the resistor 22 be larger than that of the resistors 23, 24, and 25 and the resistance value of the resistor 21 be larger than that of the resistor 22. In the case of 4-stage vertical-stacking connection, it is desired that the resistance value of the resistor 22 be larger than that of the resistors 23 and 24 and the resistance value of the resistor 21 be larger than that of the resistor 22.

### Operation

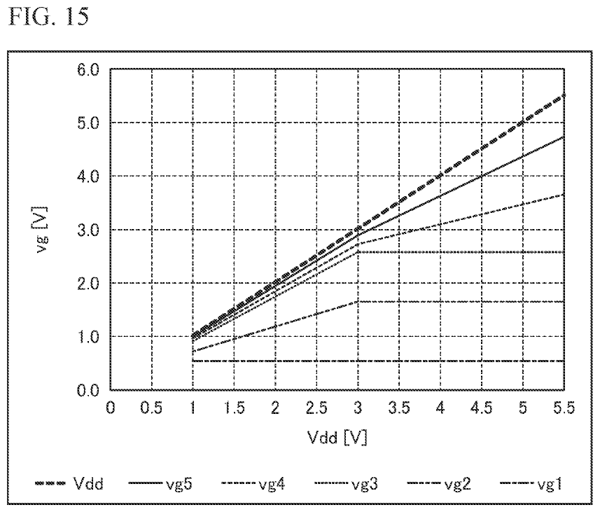

FIGS. 15, 16, and 17 are diagrams illustrating an exemplary operation of the amplification circuit 100a illustrated in FIG. 14. FIG. 15 is a diagram illustrating a simulation result of a bias applied to the gate of each FET in the amplification circuit 100a. Referring to FIG. 15, the horizontal axis represents a voltage value [V] of the power supply Vdd and the vertical axis represents a voltage value [V] of the voltage vg of a bias applied to the gate of an FET (i.e., a gate bias). FIG. 15 illustrates the change in the voltage value of each bias with respect to the change in the voltage value of the power supply Vdd.

When the voltage value of the power supply Vdd increases from 1 [V], the biases vg1 to vg5 also change with the change as illustrated in FIG. 15. However, the biases vg2 and vg3 are clamped when the voltage value of the power supply Vdd is 3 [V] and are constant in the region where the voltage value of the power supply Vdd is greater than or equal to 3 [V]. That is, not only the bias vg3 but also the bias vg2 are clamped. The principal is as follows. That is, since a voltage obtained by causing the resistors 22 and 21 and the FET 16 to divide the potential of the bias vg3 and drawing the voltage from the node between the resistors 21 and 22 is the bias vg2, the bias vg2 is similarly clamped when the bias vg3 is clamped. As illustrated in FIG. 15, the bias vg2 does not exceed approximately 1.7 [V] in the present embodiment. The bias vg3 does not exceed approximately 2.6 [V].

An FET 41 exerts the most influence on the determination of characteristics of an amplifier. The drain voltage of the FET 41 is determined in accordance with the bias vg2 of an adjacent FET 42. Accordingly, when a bias input to the clamping circuit 50, that is, a bias monitored by the clamping circuit 50, is the bias vg2 of the FET 42, the amplification circuit 100a can be driven with higher accuracy.

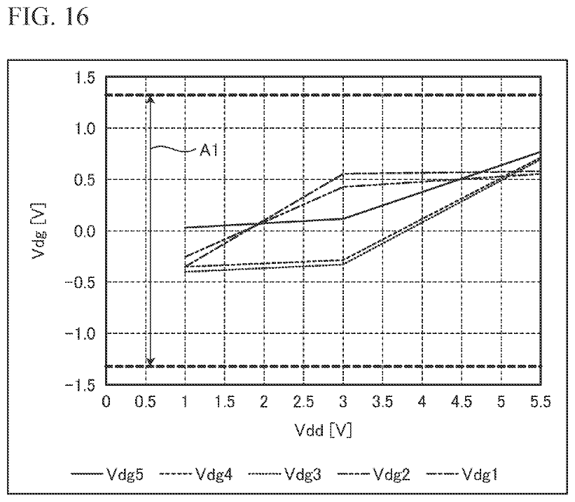

FIG. 16 illustrates a simulation result of a potential difference between a drain and a gate. Referring to FIG. 16, the horizontal axis represents a voltage value [V] of the power supply Vdd and the vertical axis represents a value [V] of a drain-to-gate voltage Vdg. When the voltage value of the power supply Vdd increases from 1 [V], the voltages Vdg corresponding to the biases vg1 to vg5 also change with the change as illustrated in FIG. 16. The voltages Vdg corresponding to the biases vg2 and vg3 are clamped when the voltage value of the power supply Vdd is 3 [V] and are constant in the region where the voltage value of the power supply Vdd is greater than or equal to 3 [V]. The voltages Vdg corresponding to the biases vg1 to vg5 do not exceed the unbroken region A1.

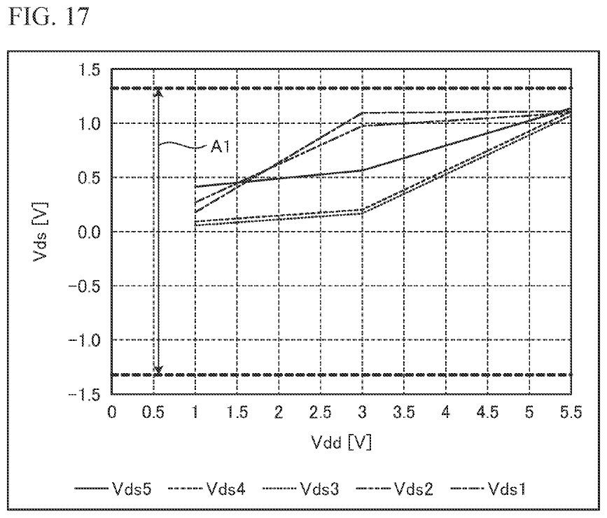

FIG. 17 illustrates a simulation result of a potential difference between a drain and a source. Referring to FIG. 17, the horizontal axis represents a voltage value [V] of the power supply Vdd and the vertical axis represents a value [V] of the drain-to-source voltage Vds. When the voltage value of the power supply Vdd increases from 1 [V], the voltages Vds corresponding to the biases vg1 to vg5 also change with the change as illustrated in FIG. 17. The voltages Vds corresponding to the biases vg2 and vg3 are clamped when the voltage value of the power supply Vdd is 3 [V] and are constant in the region where the voltage value of the power supply Vdd is greater than or equal to 3 [V]. The voltages Vds corresponding to the biases vg1 to vg5 do not exceed the unbroken region A1.

In the present embodiment, the FET 16 is provided dislike in a second embodiment to be described below. By providing the FET 16, the following effect can be obtained. That is, in the case where the threshold values of the FETs 42 to 45 vary depending on the variation in manufacturing process and the change in temperature, respective biases (vg2, vg3, vg4, and vg5) also vary by the same amount as the threshold values vary because of the presence of the FET 16. The variations in the threshold value can therefore be canceled out, and the influence of the change in the drain voltage of each FET can be suppressed.

### Effect

As described above, the amplification circuit 100a according to the present embodiment can apply an almost optimal bias to a gate when the voltage value of the power supply Vdd is small and a bias satisfying withstand voltage conditions to a gate when the voltage value of the power supply Vdd is large. That is, the drain-to-gate voltage Vdg and the drain-to-source voltage Vds can be adjusted in the unbroken region A1 as described with reference to FIGS. 16 and 17.

### Second Embodiment

Next, the second embodiment will be described.

### Configuration

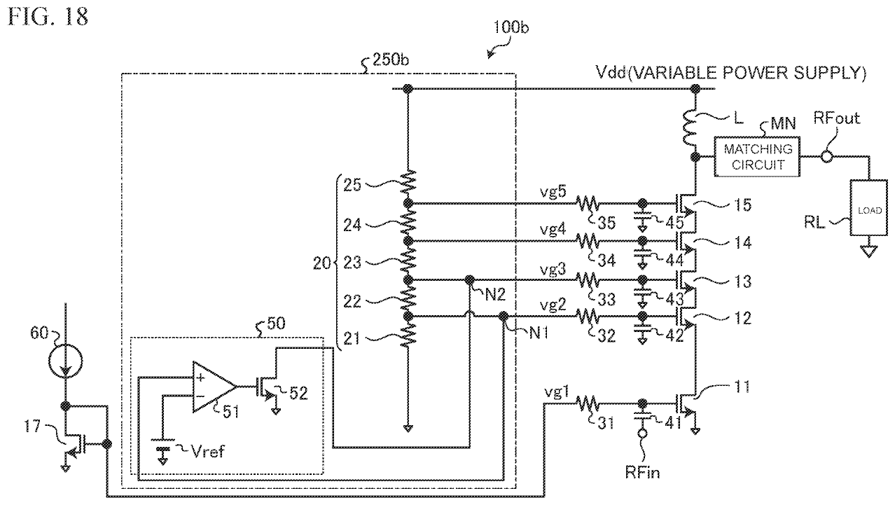

FIG. 18 is a circuit diagram of an amplification circuit 100b according to the second embodiment. The amplification circuit 100b illustrated in FIG. 18 differs from the amplification circuit 100a illustrated in FIG. 14 in that the FET 16 (see FIG. 14) between the voltage-dividing resistor circuit 20 and the reference potential is omitted. Accordingly, one end of the resistor 21 in the voltage-dividing resistor circuit 20 is directly connected to the reference potential. The voltage values of the respective biases vg2, vg3, vg4, and vg5 generated by the voltage-dividing resistor circuit 20 can be represented by the following equations (9) to (16).

That is, when vg2≤Vclamp, the following equations are satisfied.

$$v g 2 = V dd ( R 5 + R 4 + R 3 + R 2 + R 1 ) \times R 1 \qquad ( 9 )$$

$$v g 3 = V dd ( R 5 + R 4 + R 3 + R 2 + R 1 ) \times ( R 1 + R 2 ) \qquad ( 10 )$$

$$v g 4 = V dd ( R 5 + R 4 + R 3 + R 2 + R 1 ) \times ( R 1 + R 2 + R 3 ) \qquad ( 11 )$$

$$v g 5 = V dd / ( R 5 + R 4 + R 3 + R 2 + R 1 ) \times ( R 1 + R 2 + R 3 + R 4 ) \qquad ( 12 )$$

When vg2>Vclamp, the following equations are satisfied.

$$v g 2 = V clamp \qquad ( 13 )$$

$$v g 3 = V clamp + V clamp / R 1 \times R 2 \qquad ( 14 )$$

$$v g 4 = v g 3 + ( V dd - v g 3 ) / ( R 5 + R 4 + R 3 ) \times R 3 \qquad ( 15 )$$

$$v g 5 = v g 3 + ( V dd - v g 3 ) / ( R 5 + R 4 + R 3 ) \times ( R 3 + R 4 ) \qquad ( 16 )$$

### Operation

Also in the amplification circuit 100b illustrated in FIG. 18, the clamping circuit 50 is provided. Accordingly, the amplification circuit 100b operates as described with reference to FIGS. 15 to 17.

### Effect

The amplification circuit 100b according to the second embodiment can apply an almost optimal bias to a gate when the voltage value of the power supply Vdd is small and a bias satisfying withstand voltage conditions to a gate when the voltage value of the power supply Vdd is large. The amplification circuit 100b does not include the FET 16 (see FIG. 14) between the voltage-dividing resistor circuit 20 and the reference potential. Accordingly, the footprint of the amplification circuit 100b can be reduced.

### Third Embodiment

Next, the third embodiment will be described.

### Configuration

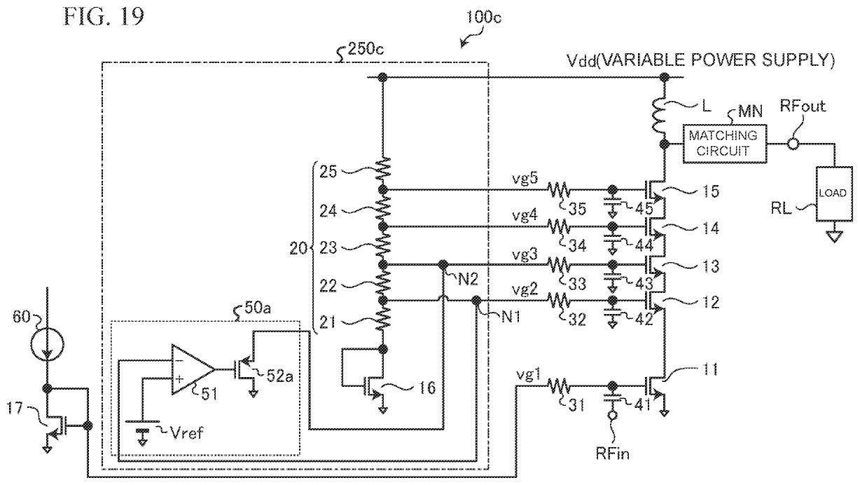

FIG. 19 is a circuit diagram of an amplification circuit 100c according to the third embodiment. As illustrated in FIG. 19, the amplification circuit 100c according to the third embodiment includes a clamping circuit 50a. That is, the amplification circuit 100c includes the clamping circuit 50a instead of the clamping circuit 50 included in the amplification circuits 100a and 100b.

In the clamping circuit 50a, a transistor 52a provided on the output side of the comparison circuit 51 is a P-type MOS transistor. That is, in the clamping circuit 50a, the transistor 52a that is not an N-type MOS transistor but a P-type MOS transistor is used. Since a PMOS transistor is used, the reference voltage Vref is input to the positive input terminal of the comparison circuit 51.

### Operation

When the voltage value of the node N1 input to the negative input terminal of the comparison circuit 51, that is, the voltage value of the bias vg2, does not exceed the reference voltage Vref, the output of the comparison circuit 51 is at a high level. At that time, the transistor 52a is in the OFF state.

When the voltage value of the node N1, that is, the voltage value of the bias vg2, exceeds the reference voltage Vref, the output of the comparison circuit 51 is at a low level. The transistor 52a is therefore brought into the ON state. When the transistor 52a is brought into the ON state, a current flows through the transistor 52a and the potential of the node N2 decreases. That is, by drawing a current from the node N2, the potential of the node N2 decreases. When the potential of the node N2 decreases, the potential of the node N1 also decreases, the amount of a current flowing through the transistor 52a decreases, and feedback is applied such that the potential of the node N1 and the potential of the reference voltage Vref are equal. That is, the voltage value of the bias vg3 is clamped to prevent the bias vg2 from exceeding the reference voltage Vref.

### Effect

The amplification circuit 100c according to the third embodiment can apply an almost optimal bias to a gate when the voltage value of the power supply Vdd is small and a bias satisfying withstand voltage conditions to a gate when the voltage value of the power supply Vdd is large. Even when a P-type MOS transistor is used as the clamping circuit 50a, the same effect obtained when an N-type MOS transistor is used can be obtained.

### Fourth Embodiment

Next, the fourth embodiment will be described.

### Configuration

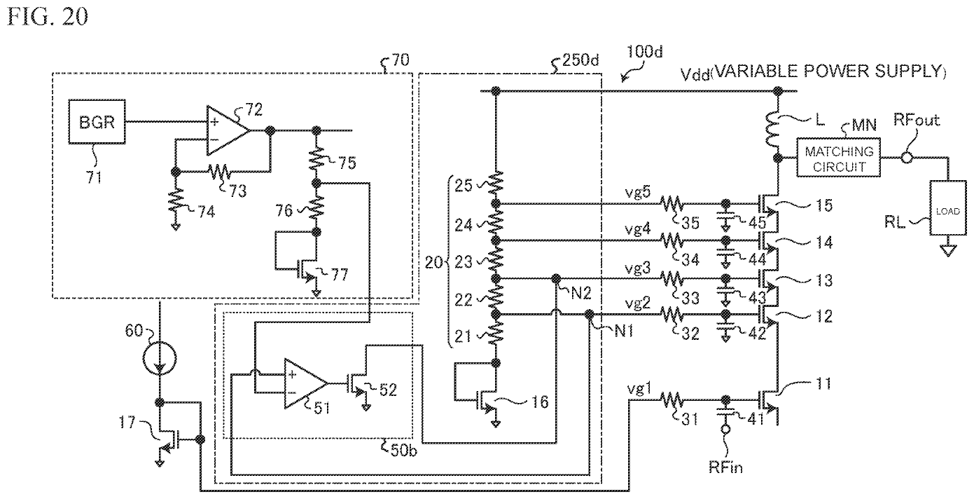

FIG. 20 is a circuit diagram of an amplification circuit 100d according to the fourth embodiment. Referring to FIG. 20, the amplification circuit 100d includes a clamp voltage generation circuit 70 for generating a reference voltage used in a clamping circuit 50b, that is, a clamp voltage.

The clamp voltage generation circuit 70 includes a bandgap reference (BGR) circuit 71, an operational amplifier 72, a non-inverting amplification circuit formed of resistors 73 and 74, and a voltage-dividing resistor circuit formed of resistors 75 and 76 and an FET 77. The bandgap reference circuit 71 is a reference voltage generation circuit for generating a reference voltage independent of, for example, a power-supply voltage and a temperature (i.e., a bandgap reference voltage). The drain and gate of the FET 77 are connected to establish a so-called diode connection. By adjusting the resistance value ratio between the resistors 73 and 74 and the resistance value ratio between the resistors 75 and 76, a desired reference voltage can be generated. A generated reference voltage is input to the negative input terminal of the comparison circuit 51 in the clamping circuit 50b.

The clamp voltage generation circuit 70 generates, along with a reference voltage generation circuit for generating a bandgap reference voltage, a constant voltage value on the basis of a bandgap reference voltage generated by the reference voltage generation circuit. The constant voltage value is set as a reference voltage for the comparison circuit 51.

### Operation

Also in the amplification circuit 100d illustrated in FIG. 20, the biases vg2 and vg3 are clamped when the power supply Vdd has a predetermined voltage value and have respective constant values in a region where the voltage value of the power supply Vdd is larger than or equal to the predetermined voltage value as illustrated in FIG. 15 like in the amplification circuit 100a. As illustrated in FIGS. 16 and 17, the voltages Vdg corresponding to the biases vg2 and vg3 and the voltages Vds corresponding to the biases vg2 and vg3 do not exceed the unbroken region A1.

### Effect

The amplification circuit 100d illustrated in FIG. 20 can also apply an almost optimal bias to a gate when the voltage value of the power supply Vdd is small and a bias satisfying withstand voltage conditions to a gate when the voltage value of the power supply Vdd is large. That is, as described with reference to FIGS. 16 and 17, the drain-to-gate voltage Vdg and the drain-to-source voltage Vds can be adjusted in the unbroken region A1.

In the amplification circuits according to the first to fourth embodiments described above, voltage dividing is performed by a plurality of series-connected resistors, respective voltages generated by the resistors are set as the biases vg2 and vg3, the biases vg2 and vg3 are applied to the corresponding gates of a plurality of FETs that are vertically stacked and connected, and the bias vg3 (the other one of the biases) is clamped when the bias vg2 (one of the biases) exceeds a predetermined reference voltage.

### Modification

The number of stages of FETs that are vertically stacked and connected is five in the first to fourth embodiments. However, the number of stages of FETs that are vertically stacked and connected is not limited thereto and may be three or more. That is, FETs may be vertically stacked and connected in at least three stages or more than three stages.

The clamping circuit 50 monitors the voltage of the bias vg2 and clamps the bias vg3 in the first to fourth embodiments. However, the clamping circuit 50 may monitor another bias and clamp still another bias.

The case where the voltage value of the power supply Vdd varies has been described above. However, an amplification circuit according to the present disclosure is applicable to the case where the voltage value of the power supply Vdd does not vary and is a constant value. However, an amplification circuit according to the present disclosure is more effectively used in the case where the voltage value of the power supply Vdd varies.

### Bias Generation Circuit

The bias generation circuit is used in the first to fourth embodiments. Referring back to FIG. 14, the amplification circuit 100a includes the bias generation circuit 250a.

The bias generation circuit 250a includes the voltage-dividing resistor circuit 20 that includes the series-connected resistors 21, 22, 23 . . . in at least three stages and generates the biases vg2, vg3, . . . from the respective stages by resistor voltage dividing and the clamping circuit 50 for, when the bias vg2 generated in a certain stage exceeds a predetermined reference voltage, clamping the bias vg3 in another stage nearer to the power supply Vdd than the certain stage. The bias generation circuit 250a applies the biases vg2, vg3, . . . to the respective gates of the FETs 12, 13, . . . that are vertically stacked and connected. The bias generation circuit 250a can apply a bias not exceeding the withstand voltage of an FET even when a power-supply voltage varies.

The amplification circuit 100b according to the second embodiment similarly includes a bias generation circuit 250b as illustrated in FIG. 18. The bias generation circuit 250b includes the voltage-dividing resistor circuit 20 and the clamping circuit 50.

The amplification circuit 100c according to the third embodiment includes a bias generation circuit 250c as illustrated in FIG. 19. The bias generation circuit 250c includes the voltage-dividing resistor circuit 20 and the clamping circuit 50a.

The amplification circuit 100d according to the fourth embodiment includes a bias generation circuit 250d as illustrated in FIG. 20. The bias generation circuit 250d includes the voltage-dividing resistor circuit 20 and the clamping circuit 50b.

### Power Amplification Circuit

By applying the above-described amplification circuit as a driver-stage amplification circuit and adding a power-stage amplification circuit to which the output of the driver-stage amplification circuit is input, a power amplification circuit usable in a communication device can be obtained.

### Configuration

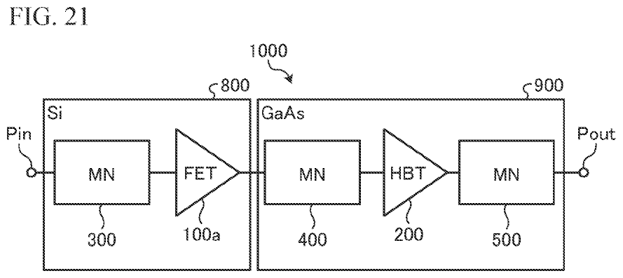

FIG. 21 is a circuit diagram illustrating an exemplary configuration of a power amplification circuit 1000. Referring to FIG. 21, the power amplification circuit 1000 includes an input terminal Pin, an input matching circuit (matching network; MN) 300, the driver-stage amplification circuit 100a, an interstage matching circuit (MN) 400, a power-stage amplification circuit 200, an output matching circuit (MN) 500, and an output terminal Pout. The power amplification circuit 1000 according to the present example is formed of two substrates 800 and 900.

In the present example, the input matching circuit 300 and the amplification circuit 100a are formed on the same substrate 800. The substrate 800 is, for example, an Si substrate. It is desired that the driver-stage amplification circuit 100a be formed of FETs that are vertically stacked and connected as described above.

In the present example, the interstage matching circuit 400, the power-stage amplification circuit 200, and the output matching circuit 500 are formed on the same substrate 900. The substrate 900 is, for example, a GaAs substrate. It is desired that the power-stage amplification circuit 200 be formed of a bipolar transistor. The power-stage amplification circuit 200 can be formed of a heterojunction bipolar transistor (HBT). The interstage matching circuit 400 and the output matching circuit 500 may be formed or disposed on a module substrate on which the substrate 800 or 900 is disposed.

As described above, the power amplification circuit 1000 includes the amplification circuit 100a applied as a driver-stage amplification circuit and also includes the power-stage amplification circuit 200 to which the output of the amplification circuit 100a is input. The power amplification circuit 1000 illustrated in FIG. 21 uses the amplification circuit 100a according to the first embodiment. Referring to FIG. 21, instead of the driver-stage amplification circuit 100a, any one of the amplification circuits 100b, 100c, and 100d may be used.

### Operation

The power amplification circuit 1000 amplifies a signal input to the input terminal Pin in the driver-stage amplification circuit 100a and further amplifies the signal in the power-stage amplification circuit 200. The signal amplified by the power-stage amplification circuit 200 is output from the output terminal Pout.

### Effect

By forming the first-stage amplification circuit 100a requiring relatively low output power with FETs as described above, the manufacturing cost of the amplification circuit can be reduced as compared with the case where the amplification circuit is formed of bipolar transistors. By forming the subsequent-stage amplification circuit 200 requiring relatively high output power with an HBT, both circuit miniaturization and favorable gain characteristics can be achieved.

The present disclosure can be embodied in the following aspects with regard to the description of Claims.
<1> An amplification circuit including:
   an input terminal to which a signal to be amplified is input;
   a first field-effect transistor (FET) having a gate to which a signal input to the input terminal is applied;
   a second FET and a third FET that, along with the first FET, are connected between a power supply and a reference potential;
   an output terminal that is provided between a load and the third FET nearer to the power supply than the second FET and that is configured to output an amplified signal;
   a voltage-dividing resistor circuit configured to generate a bias to be applied to each of respective gates of the second FET and the third FET; and
   a clamping circuit configured to clamp a bias to be applied to the gate of the third FET when a bias to be applied from the voltage-dividing resistor circuit to the gate of the second FET exceeds a predetermined reference voltage,
   wherein the first FET, the second FET, and the third FET are vertically stacked and connected.
<2> The amplification circuit according to <1>,
   wherein the voltage-dividing resistor circuit includes a first resistor, a second resistor, and a third resistor,
   wherein the first resistor is provided nearest to the reference potential,
   wherein the second resistor is provided nearer to the power supply than the first resistor,
   wherein the third resistor is provided nearer to the power supply than the second resistor, and
   wherein a resistance value of the first resistor and a resistance value of the second resistor are larger than a resistance value of the third resistor.
<3> The amplification circuit according to <2>, wherein the resistance value of the first resistor is larger than the resistance value of the second resistor.
<4> The amplification circuit according to any one of <1> to <3>,
   wherein the clamping circuit includes a comparison circuit configured to compare a voltage value of a bias to be applied from the voltage-dividing resistor circuit to the gate of the second FET with the reference voltage and a switching element that is turned on based on an output of the comparison circuit, and
   wherein, when the switching element is in an ON state, a bias to be applied to the gate of the third FET is reduced.
<5> The amplification circuit according to <4>,
   wherein, when a voltage value of a bias to be applied from the voltage-dividing resistor circuit to the gate of the second FET exceeds the reference voltage, the comparison circuit applies a voltage for turning on the switching element to the switching element, and
wherein, when the switching element is in the ON state, the comparison circuit reduces a bias to be applied to the gate of the third FET by drawing a current from a node on a path from the voltage-dividing resistor circuit to the gate of the third FET.
<6> The amplification circuit according to <4> or <5>, wherein the switching element is an N-channel or P-channel metal oxide semiconductor field-effect transistor (MOSFET).
<7> The amplification circuit according to <4> or <5>, further including:
   a reference voltage generation circuit configured to generate a bandgap reference voltage; and
   a constant voltage generation circuit configured to generate a constant voltage value based on a bandgap reference voltage generated by the reference voltage generation circuit,
   wherein a constant voltage value generated by the constant voltage generation circuit is set as the reference voltage.
<8> The amplification circuit according to any one of <1> to <5>, further including an FET that establishes a diode connection and that is provided between the voltage-dividing resistor circuit and the reference potential.
<9> The amplification circuit according to any one of <1> to <6>, further including:
   a constant current source configured to output a constant current; and
   a replica FET that forms a current mirror circuit along with the first FET,
   wherein the current mirror circuit generates a bias corresponding to a constant current output by the constant current source and applies the generated bias to the first FET.
<10> The amplification circuit according to any one of <1> to <9>,
   wherein the voltage-dividing resistor circuit includes a first resistor, a second resistor connected in series to the first resistor, and a third resistor connected in series to the second resistor,
   wherein the reference potential is connected to a side of the voltage-dividing resistor circuit where the first resistor is located and the power supply is connected to a side of the voltage-dividing resistor circuit where the third resistor is located,
   wherein a voltage generated by the first resistor is set as a bias to be applied to the gate of the second FET, and
   wherein a voltage generated by the second resistor is set as a bias to be applied to the gate of the third FET.
<11> The amplification circuit according to <10>, further including:
   a fourth FET provided between the third FET and a load; and
   a fourth resistor provided between the third resistor and the power supply,
   wherein a voltage generated by the third resistor is set as a bias to be applied to a gate of the fourth FET.
<12> The amplification circuit according to any one of <1> to <11>, wherein a voltage value of the power supply is variable.
<13> An amplification circuit including a plurality of FETs in which a drain and a source adjacent to each other are connected,
   wherein respective voltages generated by voltage dividing performed by a plurality of series-connected resistors are set as biases,
   wherein the biases are applied to corresponding gates of the plurality of FETs, and
   wherein, when one of the biases exceeds a predetermined reference voltage, another one of the biases is clamped.
<14> A power amplification circuit including:
   the amplification circuit according to any one of <1> to <13> as a driver-stage amplification circuit; and
   a power-stage amplification circuit to which an output of the driver-stage amplification circuit is input.
<15> The power amplification circuit according to <14>, wherein the power-stage amplification circuit is formed of a bipolar transistor.
<16> A bias generation circuit including:
   a voltage-dividing resistor circuit that includes series-connected resistors in at least three stages and that is configured to generate a bias from each of the at least three stages by voltage dividing; and
   a clamping circuit configured to, when the bias generated in a certain one of the at least three stages exceeds a predetermined reference voltage, clamp the bias in another one of the at least three stages nearer to a power supply than the certain stage,
   wherein the biases are applied to corresponding gates of a plurality of FETs in which a drain and a source adjacent to each other are connected.

What is claimed is:

1. An amplification circuit comprising:
an input terminal to which a signal is input for amplification;
a first field-effect transistor (FET) having a gate to which the signal input to the input terminal is applied;
a second FET and a third FET that, wherein the first FET, the second FET, and the third FET are connected between a power supply and a reference potential;
an output terminal that is between a load and the third FET and nearer to the power supply than the second FET, and that is configured to output an amplified signal;
a voltage-dividing resistor circuit configured to generate a bias applied to a gate of the second FET and a bias applied to a gate of the third FET; and
a clamping circuit configured to clamp the bias applied to the gate of the third FET when the bias applied to the gate of the second FET exceeds a predetermined reference voltage,
wherein the first FET, the second FET, and the third FET are vertically stacked and connected.

2. The amplification circuit according to claim 1,
wherein the voltage-dividing resistor circuit comprises a first resistor, a second resistor, and a third resistor,
wherein, among the first, second, and third resistor:
the first resistor is nearest to the reference potential,
the second resistor is nearer to the power supply than the first resistor, and
the third resistor is provided nearer to the power supply than the second resistor, and
wherein a resistance value of the first resistor and a resistance value of the second resistor are larger than a resistance value of the third resistor.

3. The amplification circuit according to claim 2, wherein the resistance value of the first resistor is larger than the resistance value of the second resistor.

4. The amplification circuit according to claim 1,
wherein the clamping circuit comprises a comparison circuit configured to compare a voltage value of the bias applied to the gate of the second FET with the reference voltage, and a switching circuit element that is turned ON based on an output of the comparison circuit, and
wherein, when the switching circuit element is in an ON state, the bias applied to the gate of the third FET is reduced.

5. The amplification circuit according to claim 4,
wherein, when a voltage value of the bias applied to the gate of the second FET exceeds the reference voltage, the comparison circuit is configured to apply a voltage for turning ON the switching circuit element to the switching circuit element, and
wherein, when the switching circuit element is in the ON state, the comparison circuit is configured to reduce the bias applied to the gate of the third FET by drawing a current from a node on a path from the voltage-dividing resistor circuit to the gate of the third FET.

6. The amplification circuit according to claim 4, wherein the switching circuit element is an N-channel or P-channel metal oxide semiconductor field-effect transistor (MOSFET).

7. The amplification circuit according to claim 4, further comprising:
a reference voltage generation circuit configured to generate a bandgap reference voltage; and
a constant voltage generation circuit configured to generate a constant voltage value based on a bandgap reference voltage generated by the reference voltage generation circuit,
wherein a constant voltage value generated by the constant voltage generation circuit is the reference voltage.

8. The amplification circuit according to claim 1, further comprising an FET configured to establish a diode connection and that is between the voltage-dividing resistor circuit and the reference potential.

9. The amplification circuit according to claim 1, further comprising:
a constant current source configured to output a constant current; and
a replica FET that forms a current mirror circuit with the first FET,
wherein the current mirror circuit is configured to generate a bias corresponding to a constant current output by the constant current source and to apply the generated bias to the first FET.

10. The amplification circuit according to claim 1,
wherein the voltage-dividing resistor circuit comprises a first resistor, a second resistor connected in series to the first resistor, and a third resistor connected in series to the second resistor,
wherein the reference potential is connected to a side of the voltage-dividing resistor circuit where the first resistor is located, and the power supply is connected to a side of the voltage-dividing resistor circuit where the third resistor is located,
wherein a voltage generated by the first resistor is the bias applied to the gate of the second FET, and
wherein a voltage generated by the second resistor is the bias applied to the gate of the third FET.

11. The amplification circuit according to claim 10, further comprising:
a fourth FET between the third FET and a load; and
a fourth resistor between the third resistor and the power supply,
wherein a voltage generated by the third resistor is a bias to be applied to a gate of the fourth FET.

12. The amplification circuit according to claim 1, wherein a voltage value of the power supply is variable.

13. An amplification circuit comprising a plurality of FETs in which a drain and a source adjacent to each other are connected,
wherein respective voltages generated by voltage dividing performed by a plurality of series-connected resistors are biases,
wherein the biases are applied to corresponding gates of the plurality of FETs, and
wherein, when one of the biases exceeds a predetermined reference voltage, another one of the biases is clamped.

14. A power amplification circuit comprising:
the amplification circuit according to claim 1 as a driver-stage amplification circuit; and
a power-stage amplification circuit to which an output of the driver-stage amplification circuit is input.

15. The power amplification circuit according to claim 14, wherein the power-stage amplification circuit comprises a bipolar transistor.

16. A bias generation circuit comprising:
a voltage-dividing resistor circuit comprising series-connected resistors in at least three stages, and that is configured to generate a bias from each of the at least three stages by voltage dividing; and
a clamping circuit configured to, when the bias generated in one of the at least three stages exceeds a predetermined reference voltage, clamp the bias in another one of the at least three stages nearer to a power supply than the one of the at least three stages,
wherein the biases are applied to corresponding gates of a plurality of FETs in which a drain and a source adjacent to each other are connected.
